(19) United States
(12) Patent Application Publication
(10) Pub. No.: US 2016/0126202 A1
(43) Pub. Date: May 5, 2016

(54) BRIDGING ARRANGEMENT, MICROELECTRONIC COMPONENT AND METHOD FOR MANUFACTURING A BRIDGING ARRANGEMENT

(71) Applicants: International Business Machines Corporation, Armonk, NY (US); Conpart AS, Skjetten (NO); Intrinsiq Materials Ltd., Rochester, NY (US); Jerzy Haber Institute of Catalysis and Surface Chemistry, Cracow (PL)

(72) Inventors: Thomas J. Brunschwiler, Rueschlikon (CH); Brian Burg, Rueschlikon (CH); Richard Dixon, Rochester, NY (US); Helge Kristiansen, Skjetten (NO); Piotr Warszynski, Krakow (PL); Jonas Zuercher, Rueschlikon (CH)

(21) Appl. No.: 14/880,648

(22) Filed: Oct. 12, 2015

(30) Foreign Application Priority Data
Oct. 29, 2014 (GB) 1419268.6

(51) Int. Cl. H01L 23/00

(52) U.S. Cl. CPC H01L 24/11; H01L 24/14; H01L 2224/11524

(57) ABSTRACT

A bridging arrangement includes a first and a second surface defining a gap therebetween. At least one surface of the first and second surface has an anisotropic energy landscape. A plurality of particles defines a path between the first and second surface bridging the gap.

### FOREIGN PRIORITY

This application claims priority to Great Britain Patent Application No. 1419268.6, filed Oct. 29, 2014, and all the benefits accruing therefrom under 35 U.S.C. §119, the contents of which in its entirety are herein incorporated by reference.

### FIELD OF INVENTION

The invention relates to a bridging arrangement, to a microelectronic component, and to a method for manufacturing a bridging arrangement.

### BACKGROUND

Various methods for interconnecting semiconductor devices, for example integrated circuit (IC) chips, to external circuitry, such as a circuit board, another IC chip or a wafer, are known.

For example, according to the so-called flip-chip method solder bumps are deposited onto pads of a chip. Then, the chip is flipped over, so that its top side faces down and its pads are aligned with matching pads on the external circuit. The solder is reflowed to complete the interconnect.

Further, it is known in the art to interconnect semiconductor devices using an anisotropic conductive adhesive. The anisotropic conductive adhesive has conductive particles dispersed therein. The anisotropic conductive adhesive is introduced into a gap between a respective chip pad and a matching pad on the external circuit. The anisotropic conductive adhesive layer only becomes conductive between corresponding chip pads and matching pads of the external circuit.

Yet another method for interconnecting semiconductor devices is known from U.S. Pat. No. 5,065,505. According to the method, a photocuring adhesive is applied to electrodes of a first circuit board and residual regions around the electrodes. In a further operation, the photocuring adhesive is cured only at the residual regions. Then, conductive particles are deposited on the photocuring adhesive covering the electrodes. In another operation, the first circuit board is arranged on top of a second circuit board, where corresponding electrodes of the second circuit board are electrically connected to the electrodes of the first circuit board by the conductive particles.

### SUMMARY

According to an embodiment, a bridging arrangement comprising a first and a second surface defining a gap therebetween is provided. At least one surface of the first and second surface has an anisotropic energy landscape. A plurality of particles define a path between the first and second surface bridging the gap.

According to embodiments, due to the anisotropic energy landscape the particles will only pin to certain regions of the at least one surface and not to others. Thus, a desired distribution of the particles across the at least one surface may be obtained. Further, the particles may automatically arrange themselves (also referred to as self-assembly) along a defined path or multiple defined paths as a result of the anisotropic energy landscape.

“Surface” is to include any surface, boundary or border of an object. In particular, the first and second surface may correspond to corresponding surfaces of semiconductor devices that are interconnected by the bridging arrangement.

The gap may, in addition to the plurality of particles, be filled with an underfill, for example. The underfill may, for example, comprise a curable matrix, for example an epoxy resin. The gap size may range between, for example, 1 to 100 μm, preferably (but not a necessity) 5 to 50 μm and more preferably (but not a necessity) 5 to 25 μm.

According to an embodiment, an “anisotropic energy landscape” may refer to a condition of the at least one surface that will result in the at least one surface having regions to which the plurality of particles will pin and others to which the plurality of particles will not pin. According to embodiments, “pinning” may refer to forces that cause a string of particles to develop, where at least one first particle in the string of particles contacts the first surface, intermediate particles in the string of particles contact one another, and a last particle in the string of particles contacts the second surface. This string of particles thus forms a path connecting the first and second surfaces. Further, according to embodiments, the pinning forces mentioned herein are of a magnitude that will maintain the position of particles forming said string during normal handling of the bridging arrangement during subsequent manufacturing operations, for example, when filling the gap with an underfill, and/or also during normal use of a corresponding microelectronic assembly or microelectronic component comprising the bridging arrangement. The pinning forces may include a metallic bond, a surface tension, an adhesive force, a stiction force (in particular during or after removal, e.g., evaporation, of the carrier fluid as explained hereinafter) or a magnetic force, for example. In particular, pinning forces including a metallic bond may act on the plurality of particles during an operation of annealing or melting the same.

“Particles” herein may refer to particles of essentially any shape. The particles may be of a solid material. Generally, it is hereinafter, especially in the Figures, referred to as particles of a spherical shape; yet other geometrical structures, for example tubes, of the particles are also possible. In particular, the particles may be microparticles. The particles may be of a first type. Particles of a second type may also be provided. The particles of the second type may, for example, be arranged in a contact region between a first particle of the first type and a second particle of the first type. For example, the particles of the first type may be microparticles, whereas the particles of the second type may be nanoparticles. For example, the diameter of the particles of the second type is less than one tenth or one hundredth of the diameter of the particles of the first type.

For example, the first or the second surface may have the anisotropic energy landscape. Yet, also both surfaces, i.e., the first and the second surfaces, may have an anisotropic energy landscape, respectively.

The anisotropic energy landscape may not only be defined in relation to the plurality of particles, but also in relation to a suspension having a carrier fluid and the particles as will be explained in more detail in connection with a method for manufacturing the bridge arrangement hereinafter.

In an embodiment, the at least one surface has at least one first region and at least one second region for providing the anisotropic surface. The at least one first region is configured for pinning of the plurality of particles to the at least one first region and the at least one second region being configured for non-pinning of the plurality of particles to the at least one second region.

For example, multiple first and multiple second regions are provided. Or, multiple first regions may be enclosed respectively by a second region. The first and second regions may be provided alternatingly along the length of the gap, for example. Thus, multiple paths or strings of particles bridging the gap between the first and second surface are obtained.

According to a further embodiment, the at least one first region has a first material and the at least one second region has a second material, where the first and second materials are different.

Using different materials is one way of obtaining the anisotropic energy landscape across the at least one surface. For example, the first material comprises a metal, an alloy, a metal oxide or any other material with similar properties. For example, as a metal, gold may be used. One example of a metal oxide is copper oxide. The second region may comprise a solder mask material, which is, for example, a lacquer-like layer of polymer. Other materials that may be used for the second region comprise epoxy, acrylic, benzocyclobuten (BCB), polyimide, silicon dioxide, or silicon nitride.

In a further embodiment, the first material has a first surface free energy and the second material has a second surface free energy, where the first and second surface free energies are different.

In this way, different contact angles of the carrier fluid may be obtained, thus resulting in the particles only pinning to the first and not the second material. The “surface free energy” may be defined as the excess energy at the surface of the respective material compared to the bulk.

According to a further embodiment, the first material is hydrophilic and the second material is hydrophobic.

Preferably (but not a necessity), a suspension is used that has water as a carrier fluid for the particles. The water including the particles will tend to adhere only to the first region(s) having the first material (being hydrophilic). Thus, when the water is removed, for example evaporated, particles which are in contact with the first material only (and not the second material) will remain inside the gap.

In another embodiment, the first material and/or the second material has a surface functionalization.

“Surface functionalization” herein refers to a localized surface treatment, such as for example, a deposition of molecules within the surface. For example, molecules with fluorinated end groups may be used. Another way of obtaining a surface functionalization is to use a plasma treatment.

According to a further embodiment, the at least one first region and the at least on second region have an opposite charge.

For example, the first material is negatively charged and the second material is positively charged, or vice versa. “Charged” herein refers to a localized electrical surface charging, such as for example a resulting from contact with a carrier fluid with a given pH value and the respective material.

According to a further embodiment, the first region has a first surface topology and the second region has a second topology, where the first and second surface topology are different.

“Topology” herein refers to a height profile. For instance, the height of the first region(s) is measured in a direction normal to the second region. For example, the first region(s) may protrude from the second region.

According to a further embodiment, the at least one first region and/or the at least one second region has a pad, a pillar, a trace, and/or a planar shape.

According to one example, multiple pillars or pads (first regions) protruding from a planar surface (second region) may be provided.

According to a further embodiment, each particle of the plurality of particles is 1 to 100 μm in size. In particular, 1 to 100 μm may refer to the diameter of each particle.

Further, each particle of the plurality of particles may be spherical in shape. Yet, other shapes, for example tube shapes, are contemplated.

In another embodiment, each particle of the plurality of particles includes metal, in particular solder, or metal coated, in particular solder coated, polymer spheres.

For example, the particles may be solid solder balls or spheres, or solder coated (preferably polymer but not a necessity) balls or spheres. These solder balls or solder coatings may, for example, be melted after the pinning of the balls to the first region(s), thereby, wetting of a first region(s), for example the pillars or pads, to form an electrical interconnect is easily obtained.

According to a further embodiment, the plurality of particles couples the first and second surfaces thermally and/or electrically.

Thus, the particles may not only provide for an electrical connection between the first and second surfaces but may also provide for good thermal conduction, which is important in many applications, for example in 3D chip integration.

According to a further embodiment, the first surface is a surface of an integrated circuit chip and/or the second surface is a surface of a substrate to which the integrated circuit chip is mounted by the plurality of particles.

For example, the substrate is a circuit board, another integrated circuit chip, or a wafer.

According to a further embodiment, the plurality of particles is of a first type, and the bridging arrangements further includes a plurality of particles of a second type, where particles of the second type are arranged at contact regions between particles of the first type and/or between particles of the first type and the at least one surface.

Particles of the first and second type may differ in terms of their size and/or the material they are made of. For example, the particles of the first type are microparticles and particles of the second type are nanoparticles. Preferably (but not necessarily), the particles of the second type may be configured to improve the pinning of the particles of the first type to one another and/or to the at least one first region. Further, the particles of the second type may be configured to improve the electrical contact between the particles of the first type and/or between particles of the first type and the at least one first region.

Furthermore, a microelectronic component is provided. The microelectronic component comprises an integrated circuit chip, a substrate, and at least one bridging arrangement as described above. The bridging arrangement couples the integrated circuit chip and the substrate.

Typically, the microelectronic component may comprise a plurality of the bridging arrangements as described above. The coupling may be of a thermal and/or electrical nature.

Moreover, according to an embodiment, a method for manufacturing the bridging arrangement as described above is provided. The method comprises providing at least one surface of a first and second surface defining a gap therebetween with an anisotropic energy landscape. In another operation, a suspension having a carrier fluid and particles suspended therein is introduced into the gap. Further, the carrier fluid is removed from the gap to produce a plurality of particles defining a path between the first and second surface bridging the gap.

The carrier fluid may, for example, comprise water, alcohol, or organic fluids, such as xylene, epoxy resin, or acetone.

The carrier fluid may be removed by drying or evaporating the carrier fluid at least partially. The carrier fluid may have a viscosity such that the suspended particles do not sediment. The carrier fluid may be a colloid suspension.

According to an embodiment, the carrier fluid and/or particles are selected depending on properties of the anisotropic energy landscape.

By choosing the carrier fluid and/or particles appropriately, the pinning of the particles to the first region may be improved. For example, the carrier fluid and/or particles may be selected depending on properties of the anisotropic energy landscape such as a material, a surface functionalization, or a topology of the first and second regions. In particular, the carrier fluid and/or particles may be selected to match hydrophilic and hydrophobic properties of the first and second materials.

According to an embodiment, at least one first region and/or at least one second region of the at least one surface in combination with a pH value of the carrier fluid results in pinning or non-pinning of the particles to the at least one first region and/or the at least one second region.

In other words, the at least one first region and the at least one second region in combination with a pH value of the carrier fluid result in attractive and repulsive forces on the particles which will guide these to the at least one first region and away from the at least one second region.

In the following, exemplary embodiments of the present invention are described with reference to the enclosed Figures.

### BRIEF DESCRIPTION OF THE DRAWINGS

FIG. 1A shows a sectional view related to a method corresponding to a first state in accordance with an embodiment;

FIG. 1B shows a top view taken from FIG. 1A;

FIG. 2A shows a sectional view related the method in accordance with a second state;

FIG. 2B shows a top view taken from FIG. 2A;

FIG. 3A shows a sectional view related to the method in accordance with a third state;

FIG. 3B shows a top view taken from FIG. 3A;

FIG. 4A shows a sectional view related to the method in accordance with a fourth state;

FIG. 4B shows a top view taken from FIG. 4A;

FIG. 5 shows a sectional view related to the method in accordance with a fifth state;

FIG. 6 shows an enlarged view (VI) of features from FIG. 4A;

FIG. 7 shows the view of FIG. 6 according to a further embodiment; and

FIG. 8 shows a flowchart of the method illustrated in FIGS. 1A-5.

Similar or functionally equivalent elements in the Figures have been allocated the same reference signs, if not otherwise indicated.

### DETAILED DESCRIPTION

Embodiments provide an improved bridging arrangement, an improved microelectronic device, and an improved method for manufacturing a bridging arrangement.

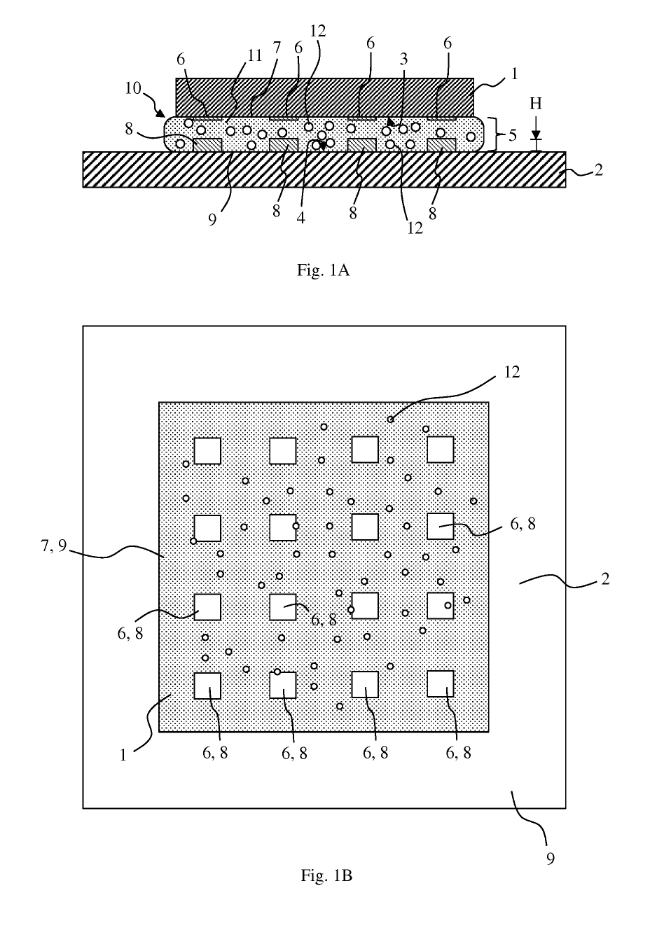

FIG. 1A shows, in a sectional view, a first component 1 arranged above a second component 2. For example, the first component 1 is an integrated circuit chip, and the second component 2 is a substrate, for example, a circuit board (PCB) or another integrated circuit chip.

The first component 1 has a first surface 3 facing a second surface 4 of the second component 2. The surfaces 3, 4 define a gap 5 therebetween.

The first surface 3 comprises a plurality of first regions 6 arranged within a second region 7. This is to say that each first region 6 is fully enclosed by the second region 7 as seen in the top view of FIG. 1B. In FIG. 1B, the first component 1 is shown partially transparent to allow components beneath the first component 1 to be seen.

For example, the first regions 6 may be configured as pads made of gold, in particular. Alternatively, the first regions 6 may be made of any other metal, for example, copper, a metal oxide (for example, copper oxide, indium tin oxide or indium zinc oxide), an alloy or a graphene based conductor. Also, the first regions 6 may comprise (native) copper oxide on a copper substrate (pad).

The second region 7 may have a planar shape, and can be made of a solder mask, i.e., a lacquer-like polymer, for example. Alternatively, the second region 7 may be made of epoxy, acrylic, BCB, polyamide, silicon dioxide, or silicon nitride.

By choosing the material for the first and second regions 6, 7 as described above, the first region 6 may be provided with hydrophilic properties and the second region 7 with hydrophobic properties. The relevance of this will be explained in more detail later.

Across from the first regions 6, the second surface 4 of the second component 2 comprises first regions 8 matching the first regions 6 of the first component 1. As can be seen from FIG. 1B, the first regions 6 of the first component 1 may cover matching first regions 8 of the second component. It is noted that the first regions 6 may be smaller or larger than the first regions 8 in other embodiments.

The first regions 8 of the second component 2 are, according to the present embodiment, configured as pillars. In terms of the material of the first regions 8 of the second component 2, the same applies as described in connection with the first regions 6 of the first component 1.

Further, the second component 2 comprises a second region 9 enclosing the first regions 8 as seen in the top view of FIG. 1B. In terms of the material of the second region 9 of the second component 2, the same applies as explained in connection with the second region 7 of the first component 1. The second region 9 may also have a planar shape.

Unlike the pads 6, which may be arranged flush (not shown in FIG. 1A) with the second region 7 (the pads 6 thus forming a plane surface with the second region 7), or may slightly protrude from the second region 7, the pillars 8 protrude from the second region 9 by a distance H. The distance H thus designates the distance H measured in a direction perpendicular to the planar surface 9 to the top of the pillars 8. Thus, the distance H, and a corresponding measurement on the first component 1, characterizes the surface topology of the first and second surfaces 3, 4.

In a further embodiment, the pads 6 or pillars 8 may be arranged in respective recesses in the second regions 7, 9 such that the distance H is negative.

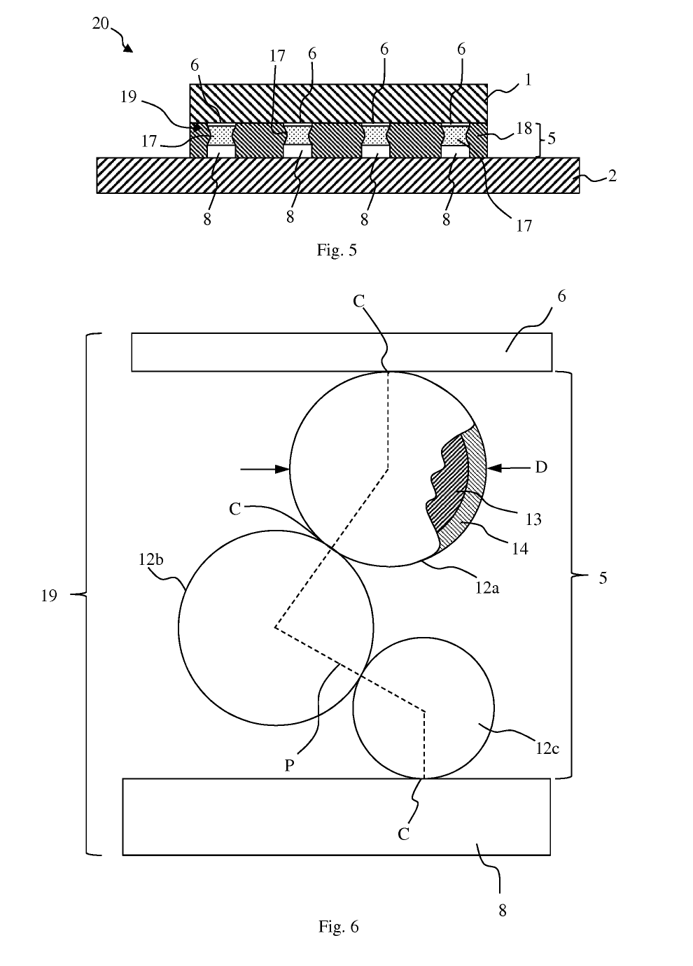

FIG. 1A also shows a suspension 10 comprising a carrier fluid 11 and suspended particles 12 arranged inside the gap 5. According to the present embodiment, the carrier fluid 11 is water, but may also be alcohol or an organic fluid, such as xylene, epoxy resin, or acetone. As shown in FIG. 6 and illustrated with respect to particles 12a, 12b, and 12c, the particles 12 may be of a spherical shape, even though other shapes may also be used. Preferably (but not a necessity), the particles 12 have a diameter D ranging between 1 and 100 μm, preferably (but not a necessity) between 1 and 50 μm, more preferably (but not a necessity) 1 and 10 μm and even more preferably (but not a necessity) 1 to 3 μm. The particles 12 may comprise a polymer sphere 13 coated with a layer 14 of metal, in particular solder. In one implementation, the particles 12 may consist exclusively of metal, in particular solder. The particles 12 may form a colloid suspension with the carrier fluid 11. The particles 12 may or may not sediment.

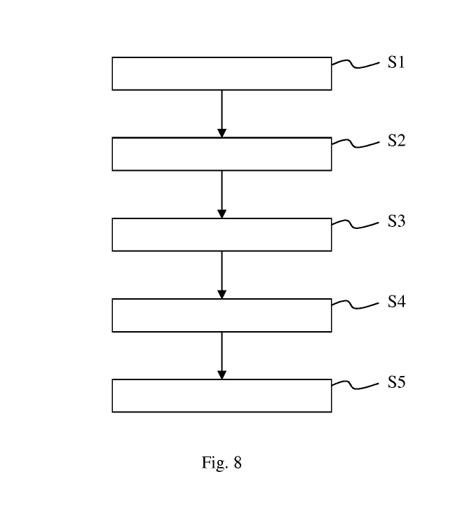

Now proceeding to FIG. 8, a number of method operations are shown.

In a first operation S1, the components 1, 2 forming the gap 5 between surfaces 3, 4 are provided (see FIG. 1A).

In a further operation S2, the suspension 10 is introduced into the gap 5 to obtain the state shown in FIG. 1A. In this state, the suspension 10 fills the entire gap 5, i.e., the suspension 10 wets all of the regions 7-9.

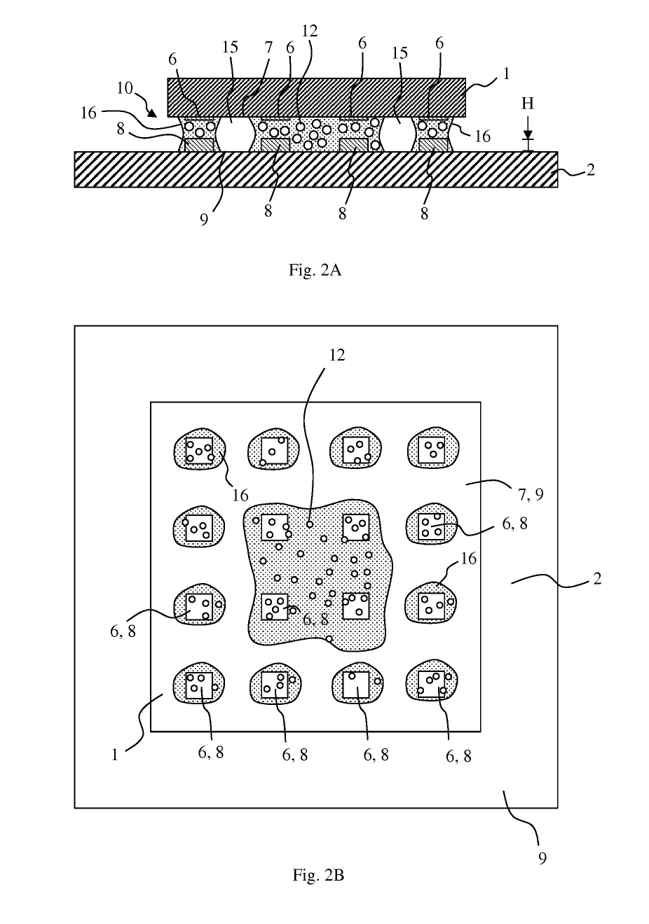

In operation S3 (see FIG. 8), the carrier fluid 11 is removed from the gap 5. Therein, FIGS. 2A-4A show different states during this removal of the carrier fluid 11. The carrier fluid 11 may, for example, be removed by evaporation. Also, the carrier fluid 11 may be drained from the gap 5 such that the particles 12 remain within the gap 5.

To this end, a suitable suction device may be used.

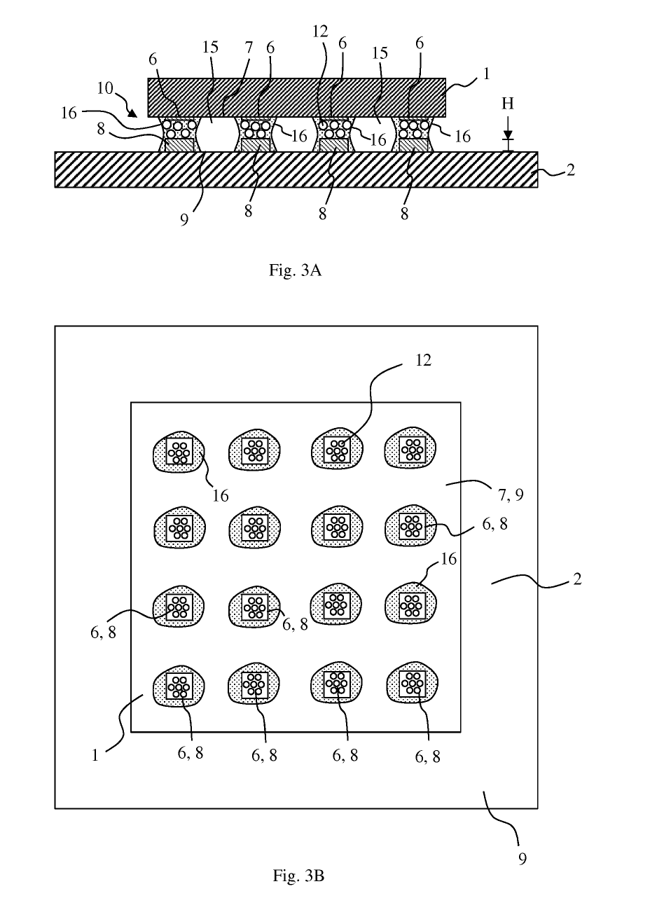

As can be seen from FIGS. 2A and 3A, the suspension 10 gathers at the first regions 6, 8, as more carrier fluid 11 is removed. On the other hand, as more carrier fluid 11 is removed, empty cavities 15 develop at the second regions 7, 9.

This gathering of the suspension 10 at the first region 6, 7, while at the same time cavities 15 are formed, is a result of an anisotropic energy landscape of the surfaces 3, 4, respectively. The anisotropic energy landscapes are, according to the present embodiment, produced through different effects. First, the materials of the first regions 6, 8 are chosen to be hydrophilic, and second regions 7, 9 are chosen to be hydrophobic. Further, the second surface 4 is provided with a surface topology (due to the pillars 8) that also promotes the formation of droplets 16 of the carrier fluid 11 at the position of the first regions 6, 8.

Yet, the respective anisotropic energy landscapes do not only interact with the carrier fluid 11 in order to guide the particles 12 to the first regions 6, 8, but also may interact with the particles 12 themselves to promote their deposition at the first regions 6, 8. To this end, the first region 6, 8 and the particles 12 are selected to be made of a material that promotes adherence or pinning of the particles 12 to the first regions 6, 8, e.g., by the tuning of the pH value of the carrier fluid 11 to yield attractive and repulsive surface charges. In addition, the anisotropic energy landscapes may comprise magnetic fields to guide the particles 12 to the first regions 6, 8.

Instead or in addition to the features described with regard to the first regions 6, 8, they may be provided with a surface functionalization to further modify or improve the anisotropic energy landscape. For example, molecules with fluorinated end groups may be deposited at the first regions 6, 8. Further, instead of or in addition to depositing the molecules, the surface functionalization may be obtained by plasma treatment of the first regions 6, 8.

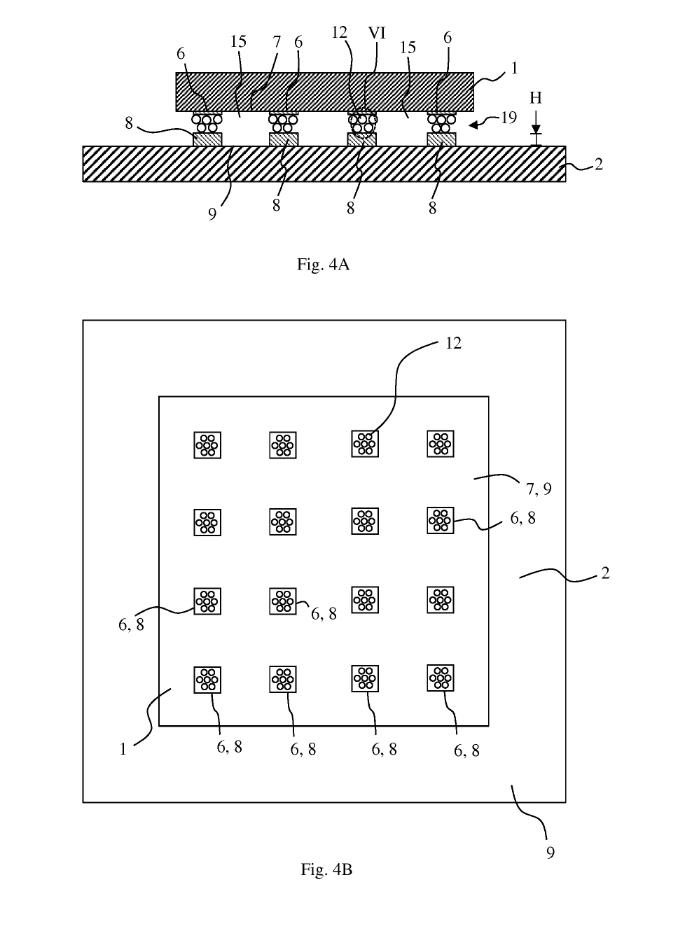

Once the carrier fluid 11 has been completely removed, the state as shown in FIG. 4A is obtained. All the particles 12 are deposited at the first regions 6, 8 (none at the second regions 7, 9). Thus, pinning of the particles 12 to the first regions 6, 8 only occurs at first regions 6, 8, whereas the second regions 7, 9 are configured for non-pinning of the particles 12 to second regions 7, 9 regions.

The pinning is shown in more detail in FIG. 6. As an example, three particles 12a, 12b, 12c are shown. The particle 12a is in direct contact with and adheres to the first region 6, i.e., is pinned thereto. The particle 12b is in direct contact with and adheres to the particle 12a and the particle 12c. The particle 12c is in turn in direct contact with and adheres to the first region 8, i.e., is pinned thereto. Corresponding connection regions are designated with the reference sign C. The particles 12a, 12b, and 12c thus form a string of particles bridging the gap 5.

FIG. 6 also shows a path P, also referred to as a percolation path, from the first region 6 of the first surface 3 via the three particles 12a, 12b, and 12c to the first region 8 of the second surface 4. Thus, a bridging arrangement 19 is obtained. According to the present embodiment, electrical power and/or electrical signals and heat may be transported via the path P from the first component 1 to the second component 2, and vice versa.

In a further operation S4 (see FIG. 8), heat is applied to the particles 12 which causes the layers of solder 14 or the entire particles 12 (when made exclusively of solder) to melt, which may result in an even better thermal and/or electrical coupling of the first and second component 1, 2 at the first regions 6, 8. This kind of soldering is referred to as reflow soldering. The soldered connections are designated with reference numeral 17 in FIG. 5.

Instead of or in addition to soldering, operation S4 may include annealing the particles 12 or parts, e.g., the layers 14, thereof.

In an operation S5 (see FIG. 8) before or after step S4, an underfill 18 may be provided in the gap 5. The underfill 18 fills the cavities 15 (see FIG. 4). The underfill 18 may be an epoxy resin, for example. Once the underfill 18 is cured, a microelectronic assembly or component 20 is obtained.

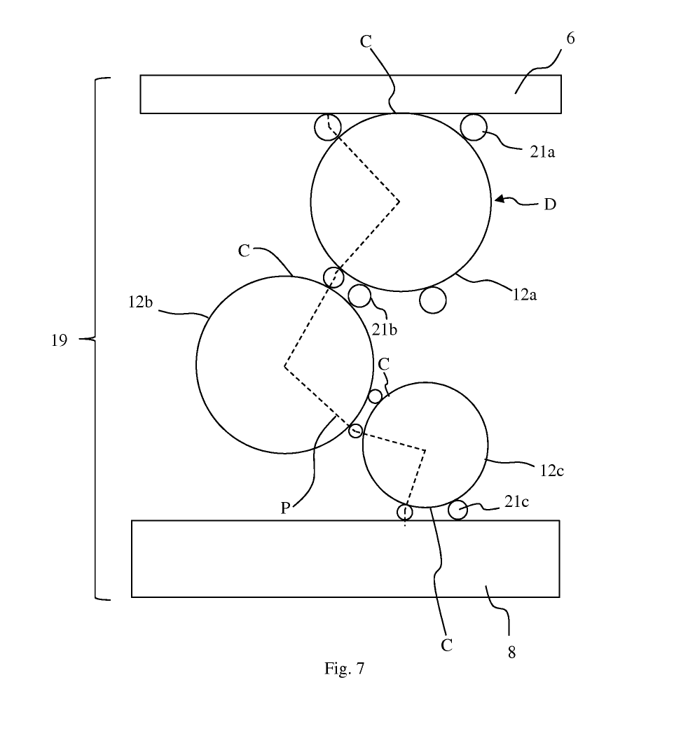

FIG. 7 illustrates a further embodiment of the bridging arrangement 19 illustrated in FIG. 6.

In addition to the particles (e.g., microparticles) 12a, 12b, and 12c, nanoparticles 21a, 21b, 21c are provided. The nanoparticles 21a, 21b, 21c may have, for example, a diameter ranging between 10 and 500 nm. The nanoparticles 12a, 12b, 12c may, for example, comprise polystyrene, silicon dioxide, aluminium dioxide, magnesium oxide, zinc oxide, silicon germanium, gallium arsenide, barium, nitride, aluminium nitride, silicon carbide, indium nitride, copper, aluminium, silver, gold, carbon, nickel, solder or iron. The nanoparticles 21a, 21b, 21c are arranged at the contact regions C between respective particles 12a, 12b, and 12c or between the particle 12a and the first region 6 or the particle 12c and the first region 8. Therein, the nanoparticles 21a may form a neck between the particle 12a and the first region 6, for example. The nanoparticles 21b may be arranged between the particles 12a and 12b, thus providing for an indirect contact between the particles 12a and 12b. The nanoparticles 21c are arranged between the particle 12c and the first region 8, thus providing for an indirect contact between the particle 12c and the first region 8. Consequently, pinning of the particles 12a, 12b, and 12c according to the embodiment of FIG. 7 is obtained also with the help of the nanoparticles 21a, 21b, 21c.

Embodiments and features described herein in relation to the method equally apply to the bridging arrangement and the microelectronic device, and vice versa. Further, “one” or “an” element is not to be understood as limiting to exactly one element but also two, three or more elements may be provided where appropriate in the mind of those skilled in the art.

More generally, while the present invention has been described with reference to certain embodiments, it will be understood by those skilled in the art that various changes may be made and equivalents may be substituted without departing from the scope of the present invention. In addition, many modifications may be made to adapt a particular situation to the teachings of the present invention without departing from its scope. Therefore, it is intended that the present invention not be limited to the particular embodiments disclosed, but that the present invention will include all embodiments falling within the scope of the appended claims.

1. A bridging arrangement comprising:
a first surface and a second surface defining a gap there between, at least one surface of the first and second surfaces having an anisotropic energy landscape; and
a plurality of particles defining a path between the first and second surfaces, thereby bridging the gap.

2. The bridging arrangement of claim 1, wherein the at least one surface has at least one first region and at least one second region for providing the anisotropic energy landscape, the at least one first region being configured for pinning of the plurality of particles to the at least one first region, and the at least one second region being configured for non-pinning of the plurality of particles to the at least one second region.

3. The bridging arrangement of claim 2, wherein the at least one first region has a first material and the at least one second region has a second material, wherein the first and the second material are different.

4. The bridging arrangement of claim 3, wherein the first material has a first surface free energy and the second material has a second surface free energy, wherein the first and second surface free energy are different.

5. The bridging arrangement of claim 4, wherein the first material is hydrophilic and the second material is hydrophobic.

6. The bridging arrangement of claim 3, wherein the first material and/or the second material has a surface functionalization.

7. The bridging arrangement of claim 2, wherein the at least one first region has a first surface topology and the at least one second region has a second surface topology, wherein the first and second surface topology are different.

8. The bridging arrangement of claim 2, wherein the at least one first region and/or the at least one second region has at least one of a pad, a pillar, a trace and/or a planar shape.

9. The bridging arrangement of claim 1, wherein each particle of the plurality of particles is 1 to 100 μm in size.

10. The bridging arrangement of claim 1, wherein each particle of the plurality of particles includes metal or metal coated polymer spheres.

11. The bridging arrangement of claim 1, wherein the plurality of particles couples the first and second surfaces at least one of thermally and/or electrically.

12. The bridging arrangement of claim 1, wherein the plurality of particles is of a first type, the bridging arrangement further including a plurality of particles of a second type; and
wherein the plurality of particles of the second type are arranged at contact regions between the plurality of particles of the first type and/or between the plurality of particles of the first type and the at least one surface.

13. The bridging arrangement of claim 1, wherein the first surface is a surface of an integrated circuit chip and/or the second surface is a surface of a substrate to which the integrated circuit chip is mounted by the plurality of particles.

14. A microelectronic component comprising:
an integrated circuit chip;
a substrate; and
at least one bridging arrangement, the bridging arrangement coupling the integrated circuit chip and the substrate.

15. A method for manufacturing a bridging arrangement, the method comprising:
providing at least one surface of a first and a second surface defining a gap there between with an anisotropic energy landscape;
introducing a suspension having a carrier fluid and particles suspended therein into the gap; and
removing the carrier fluid from the gap to produce a plurality of particles defining a path between the first and second surfaces bridging the gap.

16. The method of claim 15, wherein at least one of the carrier fluid and/or the particles are selected depending on properties of the anisotropic energy landscape of the at least one surface.

17. The method of claim 15, wherein at least one first region and/or at least one second region of the at least one surface in combination with a pH value of the carrier fluid results in pinning or non-pinning of the particles to the at least one first region and/or the at least one second region.
